(19) United States
(12) Patent Application Publication
(10) Pub. No.: US 2007/0007990 A1
(43) Pub. Date: Jan. 11, 2007

(54) Testing device with plural lenses

(75) Inventors: Zhi-An Yin, Shenzhen (CN); Yan-Kai Zhang, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/474,567

(22) Filed: Jun. 26, 2006

(30) Foreign Application Priority Data
Jun. 24, 2005 (TW) 94121216

(51) Int. Cl. G01R 31/00

(52) U.S. Cl. 324/770

(57) ABSTRACT

An exemplary testing device (2) includes plural lenses (22) for inspecting a display of a liquid crystal display (LCD) display (90), and analyzing devices (25) for receiving data obtained by the lenses and analyzing the data. The testing device including the plural lenses can collect a group of data simultaneously, and all needed data can be obtained in a short period. This helps assure that an accurate determination regarding true parameters of the brightness and uniformity of the display is made.

### FIELD OF THE INVENTION

The present invention relates to testing devices, and more particularly to a testing device typically used for testing the brightness and uniformity of liquid crystal displays (LCDs) in a manufacturing process.

### BACKGROUND

In a typical process of manufacturing LCD modules, testing and controlling the quality of each LCD is important. Characteristics of images shown by an LCD display of the LCD module are tested. Such characteristics include, for example, brightness and uniformity of the display.

FIG. 2 is a schematic, isometric view of a conventional testing device, and showing an LCD being tested. The testing device 1 includes a driving device 11, a lens 12, a first track 13, a second track 14, and an analyzing device 15. The second track 14 is horizontally disposed, and the first track 13 is vertically disposed and slidably engaged with the second track 14. The first track 13 slides on the second track 14 horizontally (as indicated by dashed arrows) to predetermined positions on command. The driving device 11 and the lens 12 are disposed on the first track 13. The driving device 11 urges the lens 12 to slide up and down along the first track 13 (as indicated by dashed arrows) to predetermined positions. The driving device 11 also urges the first track 13 to slide back and forth along the second track 14 to predetermined positions. The analyzing device 15 collects signal data from the lens 12.

In use, firstly, a display of the LCD 9 to be tested is placed in view of the lens 12. Typically, image data will be collected in respect of nine points on the display. A first set of data is collected by the lens 12 from its initial position. Then, the first track 13 slides on the second track 14 horizontally, while the driving device 11 urges the lens 12 to slide vertically, whereby the lens 12 is moved to another position at which a next set of data is collected. Typically, the lens 12 needs to be repositioned eight times to collect brightness and uniformity data in respect of nine different points on the display. Those data are transferred to the analyzing device 15 and analyzed therein. The result of the analysis is sent to an external computer 16, which then determines whether the brightness and uniformity of the display of the LCD 9 meets preset requirements.

However, the time needed for repeated repositioning of the lens 12 is relatively long, such that the display at the time of collection of the first set of data may be different from the display at the time of collection of the last set of data. That is, errors may be introduced into the data because the data were not collected within a relatively short time of each other. The errors may cause a determination error by the computer 16 regarding true parameters of the brightness and uniformity of the display of the LCD 9.

What is needed, therefore, is a testing device that overcomes the above-described deficiencies.

### SUMMARY

An exemplary testing device includes plural lenses for inspecting a display of a liquid crystal display, and plural analyzing devices for receiving data obtained by the lenses and analyzing the data.

The testing device including the plural lenses can collect a group of data simultaneously, and all needed data can be obtained in a short period. This helps assure that an accurate determination regarding true parameters of the brightness and uniformity of the display is made.

Other advantages and novel features of preferred embodiments will become more apparent from the following detailed description when taken in conjunction with the accompanying drawings.

### BRIEF DESCRIPTION OF THE DRAWINGS

FIG. 1 is a schematic, isometric view of a testing device according to an exemplary embodiment of the present invention, showing an LCD being tested.

FIG. 2 is a schematic, isometric view of a conventional testing device 1, showing an LCD being tested.

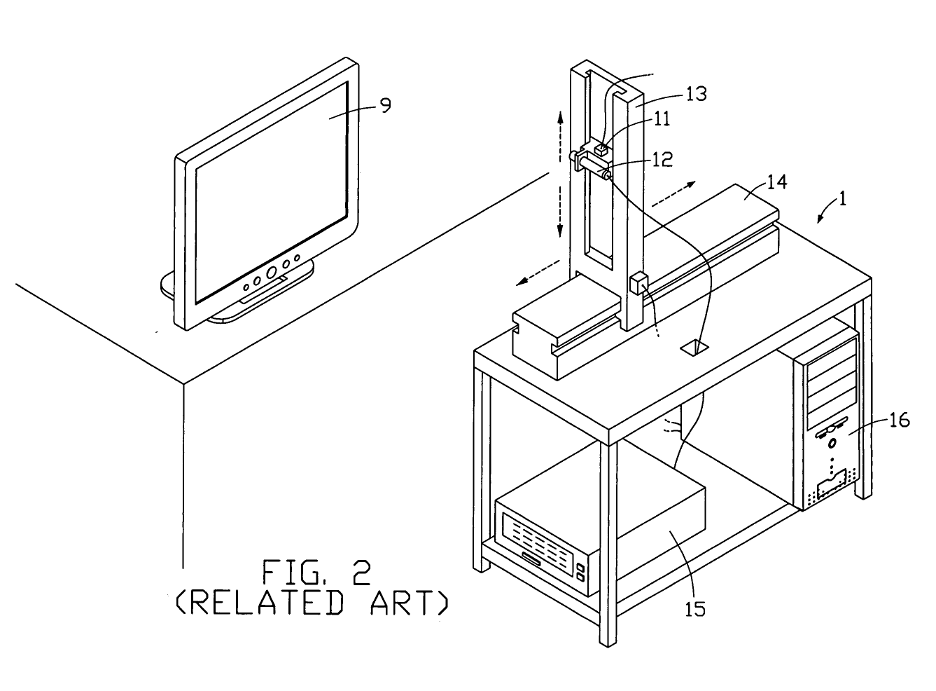

### DETAILED DESCRIPTION OF PREFERRED EMBODIMENTS

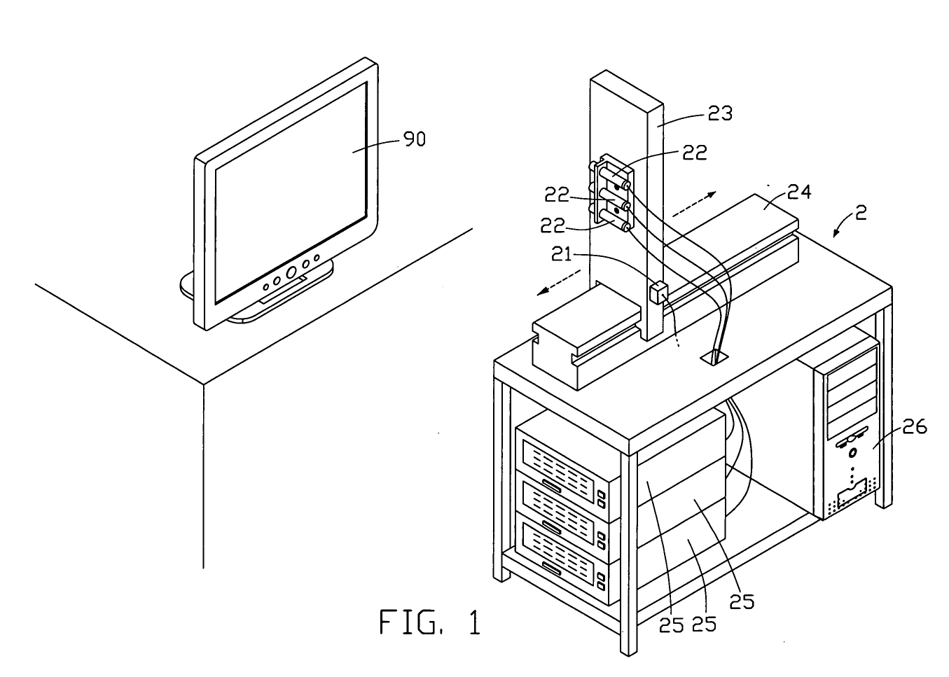

As shown in FIG. 1, a testing device 2 according to an exemplary embodiment of the present invention includes a driving device 21, three lenses 22, a tower 23, a track 24, and three analyzing devices 25. The track 24 is horizontally disposed, and the tower 23 is vertically disposed and slidably engaged with the track 24. That is, the tower 23 horizontally slides on the track 24. The lenses 22 are fixed in a bracket (not labeled), which is fixed on the tower 23. The driving device 21 urges the tower 23 with the lenses 22 to slide back and forth along the track 24. The analyzing devices 25 are respectively connected to the lenses 22 to receive signal data collected by the lenses 22.

In use, firstly, a display of an LCD 90 to be tested is placed in view of the lenses 22. Typically, data will be collected in respect of nine points on the display. A first set of data is collected by the lenses 22 from the initial position of the bracket. That is, the lenses 22 collect three groups of data simultaneously. Then, the driving device 21 urges the tower 23 with the lenses 22 to slide horizontally, whereby the lenses 22 are moved to another position at which a next set of data is collected. Thus the lenses 22 only need to be moved twice to aim at the display and collect brightness and uniformity data in respect of nine different points on the display. Those data are transferred to the analyzing devices 25 and analyzed therein. The results of the analyses are sent to an external computer 26, which then determines whether the brightness and uniformity of the display of the LCD 90 meets preset requirements.

In summary, the testing device 2 includes the three lenses 22 to collect three groups of data at any one time. The lenses 22 are oriented so they are focused on 3 different points of the display of the LCD 90; thus the lenses 22 only need to be moved twice to collect nine groups of data. The time needed for repeated repositioning of the lenses 22 is shortened, while the time taken for the lenses 22 to aim at each point is still long enough to accurately collect data. Thus the risk of the display at the time of collection of the first set of data being different from the display at the time of collection of the last set of data is minimized. The data transmitted to the computer 26 helps assure that the computer 26 makes an accurate determination regarding true parameters of the brightness and uniformity of the display of the LCD 90.

Various modifications and alterations to the above-described embodiment are possible. The bracket (not labeled) can be slidably attached on the tower 23. That is, the tower 23 can function as a second track. In such case, the driving device 21 can urge the bracket with the lenses 22 to slide up and down along the second track. Two, six, nine, or any desired number of lenses 22 may be employed, according to cost considerations and data accuracy requirements. For example, if a very high degree of accuracy is desired, data can be collected in respect of 27 points on the display of the LCD 90. In such case, nine lenses 22 can be used. In addition, the tower 23 may be horizontally disposed, and the track 24 may be vertically disposed, with the tower 23 slidably engaged with the track 24. Further, the tower 23 and the track 24 may be omitted. In such case, the lenses 22 are fixed in position, and data is collected by moving the LCD 90 under test to different positions in view of the lenses 22. Moreover, the analyzing devices 25 may be consolidated in a single analyzing device.

It is to be further understood that even though numerous characteristics and advantages of various embodiments have been set out in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A testing device, comprising:
a plurality of lenses configured for collecting data on a display of a liquid crystal display (LCD) under test; and
at least one analyzing device configured for receiving and analyzing the data.

2. The testing device as claimed in claim 1, further comprising a bracket, wherein the lenses are fixed on the bracket.

3. The testing device as claimed in claim 1, further comprising a tower and a track, wherein the lenses are fixed to the tower, and the tower is slidably attached to the track.

4. The testing device as claimed in claim 3, wherein the track is horizontally disposed, and the tower is vertically disposed and slidably engaged with the track.

5. The testing device as claimed in claim 4, further comprising a bracket, wherein the lenses are fixed on the bracket, and the bracket is fixed to the tower.

6. The testing device as claimed in claim 5, further comprising a driving device configured for driving the tower to various positions on the track.

7. The testing device as claimed in claim 1, further comprising a beam and a track, wherein the track is vertically disposed, the beam is horizontally disposed and slidably engaged with the track, and the lenses are fixed to the beam.

8. The testing device as claimed in claim 1, wherein the plurality of lenses is three lenses.

9. The testing device as claimed in claim 1, wherein the plurality of lenses is two lenses.

10. The testing device as claimed in claim 1, wherein the plurality of lenses is six lenses.

11. The testing device as claimed in claim 1, wherein the plurality of lenses is nine lenses.

12. The testing device as claimed in claim 1, wherein the at least one analyzing device is configured for transferring at least one result of analysis of the data to a computer.

13. The testing device as claimed in claim 1, further comprising a first track and a second track, wherein the second track is slidably attached to the first track, and the lenses are slidably attached to the second track.

14. The testing device as claimed in claim 13, further comprising a bracket, wherein the lenses are fixed on the bracket, and the bracket is slidably attached to the second track.

15. A testing device assembly, comprising:
a tested liquid crystal display device defining a plurality of tested point in matrix;
a plurality of lenses originated in compliance with positions of said tested points for collecting data thereof; and
at least one analyzing device configured for receiving and analyzing the data; wherein
said lenses are not required to move in both vertical and horizontal direction.

16. The assembly as claimed in claim 15, wherein said lenses are moved only in the horizontal direction.
